(19) United States
(12) Patent Application Publication
(10) Pub. No.: US 2025/0204062 A1
(43) Pub. Date: Jun. 19, 2025

(54) ELECTRONIC DEVICE

(71) Applicant: STMicroelectronics International N.V., Geneva (CH)

(72) Inventor: Arthur ARNAUD, La Tronche (FR)

(73) Assignee: STMicroelectronics International N.V., Geneva (CH)

(21) Appl. No.: 18/975,504

(22) Filed: Dec. 10, 2024

(30) Foreign Application Priority Data
Dec. 14, 2023 (FR) FR2314198

(51) Int. Cl. H10F 39/10; H10F 30/222; H10F 77/00

(52) U.S. Cl. CPC H10F 39/103; H10F 77/957; H10F 30/222

(57) ABSTRACT

An optoelectronic device includes a pixel. The pixel is formed by: a first semiconductor region; a second semiconductor region of a conductivity type different from the first conductivity type, resting on the first region; a photodiode resting on the second region, the photodiode comprising a third semiconductor region, the third region being in contact with the second region and being separated from the first region by the second region; and a first conductive and insulated element extending in the second region. A biasing circuit is configured to bias the first conductive and insulated element by a first voltage during a first operating step to allow the passing of charges from the third region to the first region.

### PRIORITY CLAIM

This application claims the priority benefit of French Application for Patent No. 2314198, filed on Dec. 14, 2023, the content of which is hereby incorporated by reference in its entirety to the maximum extent allowable by law.

### TECHNICAL FIELD

The present description generally concerns electronic devices and more particularly optoelectronic devices comprising photodiodes.

### BACKGROUND

A photodiode is a semiconductor component having the ability to capture a radiation in the optical field and to transform it into an electric signal.

### SUMMARY

An embodiment provides an optoelectronic device comprising at least one pixel, the pixel comprising: a first semiconductor region of a first conductivity type; a second semiconductor region of a second conductivity type, different from the first conductivity type, resting on the first region; a photodiode resting on the second region, the photodiode comprising a third semiconductor region of the first conductivity type, the third region being in contact with the second region and being separated from the first region by the second region; and a first conductive and insulated element extending in the second region, the first element being configured to be biased by a first voltage, during a first operating step, to allow the passing of charges from the third region to the first region.

Another embodiment provides a method of controlling an optoelectronic device comprising at least one pixel, the pixel comprising: a first semiconductor region of a first conductivity type; a second semiconductor region of a second conductivity type, different from the first conductivity type, resting on the first region; a photodiode resting on the second region, the photodiode comprising a third semiconductor region of the first conductivity type, the third region being in contact with the second region and being separated from the first region by the second region; and a first conductive and insulated element extending in the second region, the method comprising a first operating step during which the conductive core of the first element is biased by a first voltage to allow the passing of charges from the third region to the first region.

According to an embodiment, the first element is a via comprising a conductive core and an insulating sheath extending through the first and second regions.

According to an embodiment, the conductive core of the first element comprises a first portion surrounded by the first region and a second portion surrounded by the second region, the second portion having horizontal dimensions greater than the horizontal dimensions of the first portion.

According to an embodiment, the photodiode comprises the third doped region of the first conductivity type and a fourth doped region of the second conductivity type, the third region comprising first and second layers forming a heterojunction, the first layer being made of a semiconductor material and the second layer comprising quantum dots, the fourth region being in contact with the second layer, the dopant concentration of the first layer being greater than that of the second layer.

According to an embodiment, the pixel comprises a first insulated conductive wall surrounding the first region, the first wall being configured to be biased in such a way as to deplete the first region.

According to an embodiment, the pixel comprises a second insulating wall surrounding the first region, and a second insulated conductive element extending in the first region.

According to an embodiment, the first region is divided into first and second portions, the first element being located in the second region, in front of the first portion of the first region, the first and second portions of the first region being separated by a third insulating wall, the pixel comprising a third element, the third element being conductive and insulated, the third element extending in the second region in front of the second portion of the first region, the third element being configured to be biased by a second voltage, during a second operating step, to allow the passing of charges from the third region to the second portion of the first region.

According to an embodiment, the pixel is configured so that, during the first operating step, the third element is biased by a third voltage in such a way as to block the passing of charges from the third region to the second portion of the first region and wherein the pixel is configured so that, during the second operating step, the first element is biased by a fourth voltage in such a way as to block the passing of charges from the third region to the first portion of the first region.

According to an embodiment, the first region is divided into at least two first portions and a second portion, the pixel comprising as many first elements as there are first portions, each first element being located in the second region in front of one of the first portions of the first region, the first and second portions of the first region being separated from one another by a third insulating wall, the pixel comprising a third element, the third element being conductive and insulated, the third element extending in the second region in front of the second portion of the first region, the third element being configured to be biased by a second voltage, during a second operating step, in such a way as to allow the passing of charges from the third region to the second portion of the first region.

According to an embodiment, the pixel comprises as many second insulated conductive elements as there are first portions of the first region, each second element extending in one of the first portions of the first region.

According to an embodiment, during the first operating step, the third element is biased by a third voltage in such a way as to block the passing of charges from the third region to the second portion of the first region and wherein the pixel is configured so that, during the second operating step, the first elements are biased by a fourth voltage in such a way as to block the passing of charges from the third region to the first portions of the first region.

According to an embodiment, the first region is divided into at least two first portions, the pixel comprising as many first elements as there are first portions, each first element being located in the second region in front of one of the first portions of the first region.

According to an embodiment, the pixel is configured to operate in a succession of steps, each step comprising the application of a voltage to the first element of one of the first portions so as to allow the passing of charges to said first portion and the application of a voltage to the other first elements so as to block the passing of charges to the other first portions.

According to an embodiment, each first portion is surrounded by a first insulated conductive wall, the first wall being configured to be biased in such a way as to deplete said first region.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1A shows a cross-section view of an embodiment of an electronic device;

FIG. 1B shows a top view of the embodiment of FIG. 1A;

FIG. 2A shows a cross-section view of another embodiment of an electronic device;

FIG. 2B shows a top view of the embodiment of FIG. 2A;

FIG. 3 shows a cross-section view of another embodiment of an electronic device;

FIG. 4A and FIG. 4B illustrate the operation of the embodiment of FIG. 3;

FIG. 5A shows a cross-section view of another embodiment of an electronic device;

FIG. 5B shows a cross-section view of another embodiment of FIG. 5A;

FIG. 5C shows a top view of the embodiment of FIG. 5A;

FIG. 5D shows another cross-section view of the embodiment of FIG. 5A;

FIG. 6A shows a cross-section view of another embodiment of an electronic device; and

FIG. 6B shows a top view of the embodiment of FIG. 6A.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

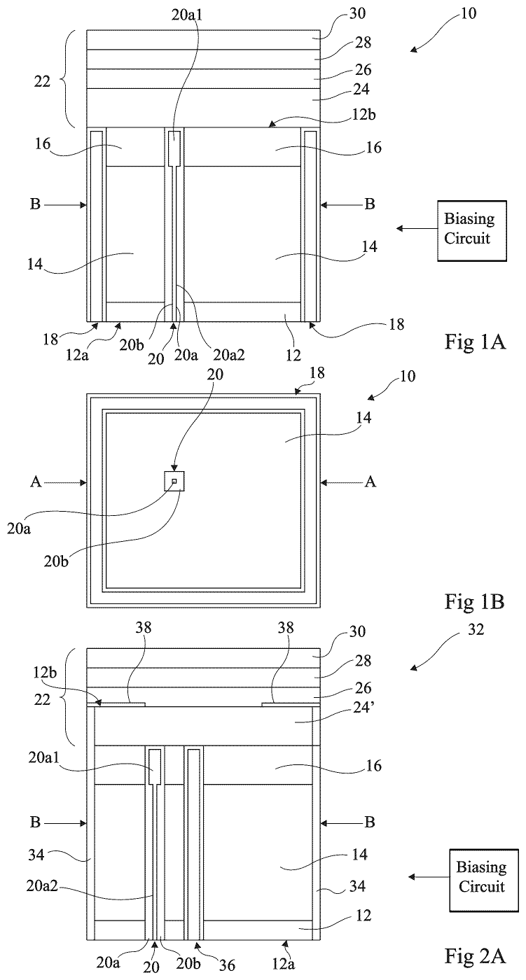

FIG. 1A shows a cross-section view of an embodiment of an electronic device. FIG. 1B shows a top view of the embodiment of FIG. 1A. More precisely, FIG. 1A is a cross-section view along plane A-A of FIG. 1B and FIG. 1B is a top view along plane B-B of FIG. 1A.

The device is, for example, an optoelectronic device. The device comprises at least one pixel 10, preferably a plurality of pixels, for example at least one hundred pixels, for example at least one thousand pixels. For example, the pixels are arranged in an array. The device is, for example, configured to generate one or a plurality of electric signals on reception of light signals. For example, the device is a camera or a light sensor, for example, a time-of-flight sensor.

Pixel 10 is located inside and on top of a substrate 12. Substrate 12 is made of a semiconductor material, for example of silicon. Substrate 12 comprises a first surface 12a, or lower surface, and a second surface 12b, or upper surface, opposite to first surface 12a. Electronic components, not shown, are located inside and on top of substrate 12 on the side of first surface 12a. Thus, transistors may be formed inside and on top of substrate 12, more precisely on the side of surface 12a. The transistors comprise, for example, a source region and a drain region flush with surface 12a and a gate located on surface 12a. An interconnection network, not shown, that is, a stack of insulating layers comprising conductive tracks and conductive vias so as to allow electric connections, is for example located on surface 12a of the substrate.

Pixel 10 comprises a storage region 14. Region 14 corresponds to a doped well of substrate 12. Well 14 is located on the side of surface 12b. Preferably, well 14 is separated from surface 12a of substrate 12 by the portions of the substrate having the electronic components, for example, the transistors, located therein. Well 14 is made of a semiconductor material, for example of the same material as substrate 12, for example of silicon. Well 16 is, for example, N-type doped. Well 14 is, for example, made of a single material, for example homogeneous. The dopant concentration in well 14 is, for example, in the range from 5*10¹⁵ cm⁻³ to 5*10¹⁶ cm⁻³.

Pixel 10 further comprises another region 16. Region 16 corresponds to a doped well of substrate 12. Well 16 is located on the side of surface 12b. Preferably, well 16 is flush with surface 12b of substrate 12. Well 16 is made of a semiconductor material, for example of the same material as substrate 12, for example of silicon. Well 16 is doped with the type opposite to the doping type of region 14, for example P-type doped. Well 16 is, for example, made of a single material, for example homogeneous. The dopant concentration in well 16 is, for example, in the range from 10¹⁷ cm⁻³ to 5*10¹⁸ cm⁻³. The upper surface of well 14 is preferably in contact with the lower surface of well 16.

Pixel 10 comprises a wall 18. Wall 18 is conductive and insulated. In other words, wall 18 comprises a conductive core, for example made of metal, and an insulating outer sheath at least laterally surrounding the conductive core. Wall 18 laterally surrounds wells 14 and 16. The side walls of wells 14 and 16 are, for example, in contact with the side walls of the sheath of wall 18.

Wall 18 extends at least along the height of wells 14 and 16. In other words, wall 18 extends at least along the side walls of wells 14 and 16. Preferably, wall 18 extends all along the height of substrate 12.

The electronic components located in the region of substrate 12 surrounded by wall 18 are, for example, components associated with the pixel, for example components forming the pixel control circuit or components of the circuit for processing the information obtained by the pixel.

The conductive core of wall 18 is configured to receive a voltage from a biasing circuit. The core of wall 18 is, for example, coupled to a node of application of said voltage via conductive tracks and conductive vias of the interconnection network, not shown. Said voltage is preferably configured to allow the depletion of well 14.

The pixel further comprises an element 20. Element 20 comprises a conductive core 20a and an insulating sheath 20b. Element 20 preferably extends at least along the height of wells 14 and 16. Element 20 extends, for example, all along the height of substrate 12, that is, from surface 12a to surface 12b. At the end of element 20 flush with surface 12a, conductive core 20a is, for example, exposed (meaning that it is, for example, not covered by sheath 20b) to be electrically coupled to a voltage source of the biasing circuit, for example via conductive tracks and vias of the interconnection network, not shown.

The conductive core 20a of element 20 preferably comprises two portions 20al and 20a2. Portions 20al and 20a2 are in contact. Thus, portion 20al comprises a lower end in contact with the upper end of portion 20a2. Portion 20al preferably has horizontal dimensions greater than the horizontal dimensions of portion 20a2. By horizontal, there is meant in a plane parallel to cross-section plane B-B.

Portion 20al is located in line with well 16. In other words, portion 20al preferably has a height smaller than or equal to the height of well 16. More precisely, the portion of the element 20 comprising portion 20al is laterally surrounded by well 16. Preferably, the portion of element 20 comprising portion 20al is not laterally surrounded by well 14. The upper end of portion 20al is preferably covered by sheath 20b.

Portion 20a2 is located in line with well 14. Portion 20a2 preferably extends from surface 12a to the lower end of portion 20a1, for example located at the interface between well 14 and well 16. More precisely, the portion of element 20 comprising portion 20a2 is laterally surrounded by well 14, by the portion of substrate 12 comprising the electronic components, not shown, and optionally by a portion of well 16.

Element 20 preferably extends in a central portion of the pixel (but not necessarily centered therein). Thus, element 20 is separated from wall 18, preferably from all the portions of wall 18, by portions of substrate 12.

Pixel 10 further comprises a photodiode 22. The photodiode is located on surface 12b of the substrate. Preferably, photodiode 22 is in contact with surface 12b, preferably in contact with well 16 and with element 20. Preferably, photodiode 22 covers the entire portion of substrate 12 corresponding to the pixel. Thus, the photodiode preferably covers the entire portion of substrate 12 surrounded by wall 18.

Photodiode 22 may be any type of photodiode comprising a semiconductor layer 24 of the same doping type as well 14, for example N-type doped. Layer 24 is preferably in contact with surface 12b, preferably in contact with well 16 and with element 20. Preferably, layer 24 covers the entire portion of substrate 12 corresponding to pixel 10. Thus, layer 24 preferably covers the entire portion of substrate 12 surrounded by wall 18.

In the example of FIGS. 1A and 1B, layer 24 is made of a semiconductor material, for example of the same material as substrate 12, for example of silicon. Layer 24 forms a portion of the cathode of the photodiode. Layer 24 is, for example, made of a single material, for example homogeneous. The dopant concentration in layer 24 is, for example, substantially equal to 10¹⁶ dopants per cm³.

Pixel 10 comprises a transistor formed by wells 14, 16, layer 24, and element 20.

In the example of FIGS. 1A and 1B, photodiode 22 comprises a layer 26. Layer 26 covers the upper surface of layer 24. More precisely, layer 26 covers at least the portion of layer 24 corresponding to pixel 10, that is, being located in front of the portion of substrate 12 surrounded by wall 18. Layer 26 preferably covers layer 24. Layer 26 is preferably in contact with layer 24.

Layer 26 forms another portion of the cathode of the photodiode of the pixel. Layer 26 comprises quantum dots of the same conductivity type as layer 24, for example N-type. Layer 26 forms the photosensitive layer of the photodiode.

A quantum dot or semiconductor nanoparticle is a structure comprising a nanoscopic material which generates electron-hole pairs in the presence of the incidence of photons on the structure comprising a nanoscopic material.

A quantum dot comprises a semiconductor core. A quantum dot may also comprise a shell, preferably made of a semiconductor material, surrounding the core to protect and to passivate the core. A quantum dot further comprises ligands, organic aliphatic compounds, organometallic or inorganic molecules which extend from the shell and passivate, protect, and functionalize the semiconductor surface.

The composition of a quantum dot may be selected from among the following materials. The core is for example made of a material from among the following materials or from among an alloy of the following materials: CdSe, CdS, CdTe, CdSeS, CdTeSe, AgS, ZnO, ZnS, ZnSe, CuInS, CuInSe, CuInGaS, CuInGaSe, PbS, PbSe, PbSeS, PbTe, InAsSb, InAs, InSb, InGaAs, InP, InGaP, InAlP, InGaAlP, InZnS, InZnSe, InZnSeS, HgTe, HgSe, HgSeTe, Ge, Si. The shell is, for example, made of a material from among the following materials or from among an alloy of the following materials: CdSe, CdS, CdTe, CdSeS, CdTeSe, AgS, ZnO, ZnS, ZnSe, CuInS, CuInSe, CuInGaS, CuInGaSe, PbS, PbSe, PbSeS, PbTe, InAsSb, InAs, InSb, InGaAs, InP, InGaP, InAlP, InGaAlP, InZnS, InZnSe, InZnSeS, HgTe, HgSe, HgSeTe, Ge, Si.

Preferably, all the core dimensions are smaller than 20 nm, for example in the range from 2 to 15 nm. In particular, the diameter of each quantum dot is preferably in the range from 2 to 15 nm. By diameter, there is meant the diameter of the smallest sphere in which the quantum dot can be inscribed.

It is possible to select a size and a dimension of quantum dots capable of absorbing, with a significant absorption, any wavelength in a wide wavelength range. For example, it is possible to find a size and a dimension of quantum dots having an operating wavelength greater than 300 nm, for example between 300 nm and 3,000 nm, which includes the visible, infrared, near infrared, and short infrared range. For example, layer 26 comprises lead sulfide quantum dots, for example, quantum dots having a radius smaller than 10 nm, to obtain an absorption peak linked to the quantum confinement in infrared, while allowing the absorption of wavelengths in the visible range.

Layer 26 has, for example, a thickness in the range from 100 nm to 500 nm. Well 16 has, for example, a thickness in the range from 2 μm to 10 μm.

The doping of layer 26, for example in the range from 10¹⁵ dopants per cm³ to 10¹⁶ dopants per cm³, is lighter than the doping of layer 24, that is, than the dopant concentration in layer 24, to enable layer 26 to be fully depleted by layer 24 and a voltage to be applied to the photodiode anode.

The interface between layer 26 and layer 24 forms a heterojunction. Preferably, the upper surface of layer 24 is treated, for example before the forming of layer 26, to ensure the forming of the heterojunction. The upper surface of layer 24 is, for example, treated with a self-assembled monolayer (SAM), for example, made of CH₃I or of one or a plurality of other halogenated compounds. The monolayer is for example replaced with a thin layer of metal oxide, for example of ZnO. The upper surface of layer 24 is for example treated with a halogen treatment.

Pixel 10 further comprises a layer 28. Layer 28 is a hole extraction layer. Layer 28 is of the conductivity type opposite to the conductivity type of layers 24 and 26, for example P-type. Layer 28 is, for example, made of a P-type doped metal oxide or comprises, for example, quantum dots behaving like a P-type material due to the position of its Fermi level relative to the Fermi level of the material of layer 26. Layer 28 corresponds to the anode of the photodiode. Layer 28 is transparent to the operating wavelengths of the pixel.

Layer 28 covers the upper surface of layer 26. Preferably, layer 28 covers at least the portion of layer 26 located in front of layer 24. Layer 28 is preferably in contact with layer 26, for example at least with the portion of layer 26 facing wells 14 and 16. The interface between layer 26 and layer 28 corresponds to a PN junction of the photodiode, enabling to extract the photogenerated carriers, the photogenerated carriers being holes in the case of an N-doped layer 24.

Pixel 10 further comprises a layer 30. Layer 30 is a conductive layer, for example made of metal oxide. Layer 30 is transparent to the operating wavelengths of the pixel. Layer 30 is, for example, made of MoO₃, ITO, Va₂O₅, NiO, CuO, or of sub-stoichiometric WO₃. Layer 30 forms part of the anode of the photodiode in the case where it is used to collect holes.

Layer 30 covers the upper surface of layer 28. Preferably, layer 30 covers at least the portion of layer 28 located in front of wells 14 and 16. Layer 30 is preferably in contact with layer 28, for example at least with the portion of layer 26 located in front of well 16.

The operation of the pixel comprises first operating steps (or phases) during which a first voltage is applied to element 20 from a voltage source of the biasing circuit and second operating steps (or phases) during which a second voltage is applied to element 20 from a voltage source of the biasing circuit.

The first voltage is configured to turn off a vertical metal-oxide-semiconductor field-effect transistor (MOSFET), said transistor being formed by the element 20 forming the gate and by wells 14, 16 and the layer 24 used as a channel. Thus, during the first steps, the charges located in layer 24 are held in layer 24. For example, the first steps correspond to measurement steps (or phases), in which charges are generated by photodiode 22. Preferably, part of the charges, for example the electrons if layer 24 is N-type doped, is stored in layer 24 and the other part of the charges, for example holes, are attracted to layer 30.

The second voltage is configured to turn on a MOSFET transistor, said transistor being formed by the element 20 forming the gate and by wells 14, 16 and layer 24 being used as a channel. Thus, during the second steps, charges located in layer 24 are transmitted into well 14. For example, the second steps correspond to storage steps (or phases).

For example, the charges stored in well 14 may be read out, that is, supplied to a readout circuit for example located in substrate 12, during the first steps.

The operation of pixel 10 comprises, for example, an alternation of first and second steps. Thus, the operation of pixel 10 may periodically comprise second steps, the second steps being separated from one another by first steps.

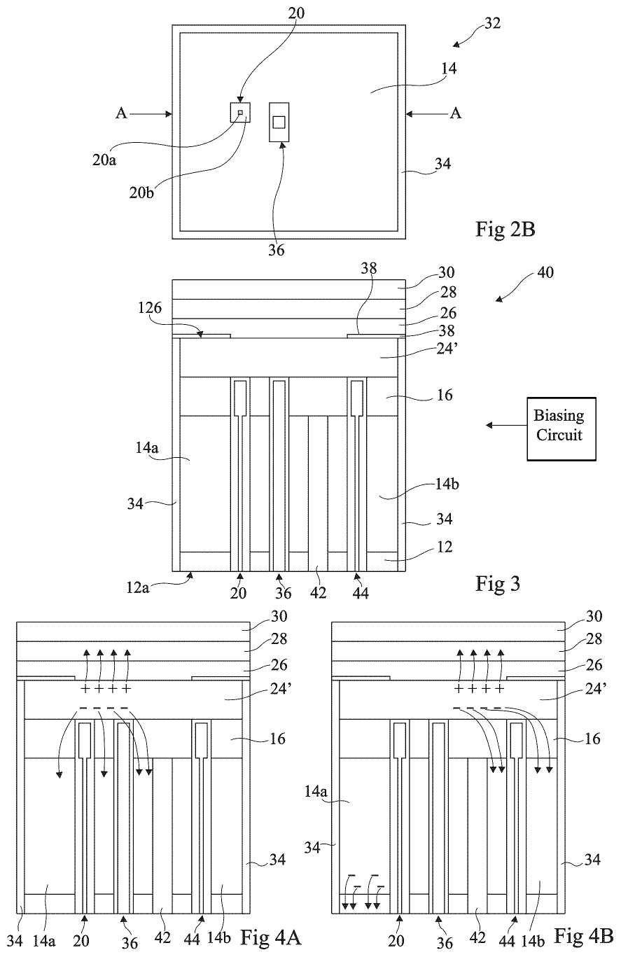

FIG. 2A shows a cross-section view of another embodiment of an electronic device. FIG. 2B shows a top view of the embodiment of FIG. 2A. More precisely, FIG. 2A is a cross-section view along plane A-A of FIG. 2B and FIG. 2B is a top view along plane B-B of FIG. 2A.

The device is, for example, like the device 10 of FIGS. 1A and 1B, an optoelectronic device. The device comprises at least one pixel 32, preferably a plurality of pixels 32, for example at least one hundred pixels, for example at least one thousand pixels. For example, the pixels 32 are arranged in an array. The device of FIGS. 2A and 2B is, for example, configured to generate one or a plurality of electric signals on reception of light signals. For example, the device is a camera or a light sensor, such as a time-of-flight sensor.

Pixel 32 comprises elements of pixel 10 which will not be described again in detail. In particular, pixel 32 comprises: substrate 12, having surfaces 12a and 12b; wells 14 and 16 in substrate 12; element 20 in substrate 12; and layers 26, 28, 30.

Pixel 32 differs from pixel 10 in that pixel 32 does not comprise layer 24, but comprises a well 24′. Well 24′ is a doped well of substrate 12. Well 24′ is located on the side of surface 12b. Preferably, well 24′ is flush with surface 12b of substrate 12. Well 24′ is made of a semiconductor material, for example of the same material as substrate 12, for example of silicon. Well 24′ is doped with the same doping type as region 14, for example N-type. Well 24′ is, for example, made of a single material, for example homogeneous. The dopant concentration in well 24′ is, for example, in the range from 5*10¹⁵ cm⁻³ to 5*10¹⁶ cm⁻³, for example equal to the dopant concentration in the layer 24 of FIGS. 1A and 1B.

Thus, in FIGS. 2A and 2B, well 16 is not flush with surface 12b of substrate 12. Well 16 is buried in substrate 12. The well is located between well 24′ and well 14. The upper surface of well 14 is preferably in contact with the lower surface of well 16. The upper surface of well 16 is preferably in contact with the lower surface of well 24′.

Element 20 extends, as in FIGS. 1A and 1B, from surface 12a to the upper surface of well 16. In FIGS. 2A and 2B, element 20 does not extend all the way to surface 12b of substrate 12. In other words, element 20 preferably does not extend in well 24′.

Pixel 32 further differs from pixel 10 in that pixel 32 does not comprise the wall 18 surrounding wells 14 and 16. Pixel 32 comprises an insulating wall 34. Wall 34 is, preferably entirely, made of an insulating material, for example of silicon oxide. Wall 34 replaces wall 18. Thus, wells 14 and 16 are surrounded, as in FIGS. 1A and 1B, by wall 34. Wells 14, 16, 24′ are surrounded by wall 34. Like wall 18, wall 34 preferably extends all along the height of substrate 12, that is, from surface 12a to surface 12b. Thus, in FIGS. 2A and 2B, wall 34 extends at least all along the height of wells 14, 16, and 24′.

Pixel 32 further comprises an element 36. Element 36 is, for example, an insulated conductive via. In other words, element 36 comprises a conductive core, for example made of metal, and an insulating outer sheath at least laterally surrounding the conductive core. Element 36 crosses wells 14 and 16. In other words, element 36 preferably extends at least all along the height of wells 14 and 16. Element 20 extends, for example, from surface 12a to the upper surface of well 16.

At the end of element 36 flush with the upper surface of well 16, the conductive core is for example insulated, that is, is for example covered by the insulating sheath. At the end of element 36 flush with surface 12a, the conductive core is for example exposed (meaning that it is not covered by the insulating sheath) to be electrically coupled to a voltage source of the biasing circuit, for example via the conductive tracks and vias of the interconnection network, not shown. Said voltage is, like the voltage applied to the wall 18 of FIGS. 1A and 1B, preferably configured to allow the depletion of well 14.

Alternatively, element 36 may extend all along the height of substrate 12, that is, from surface 12a to surface 12b.

Element 36 preferably extends in a central portion of well 14 (but is not necessarily centered therein). Thus, element 36 is separated from wall 34, preferably from all the portions of wall 34, by portions of substrate 12, preferably by portions of well 14. Element 36 and element 20 are preferably separated from each other by portions of substrate 12, preferably by portions of well 14.

Pixel 32 comprises, for example, layers 38. Layers 38 are made of an insulating material. The layers 38 are located at the interface between well 24′ and layer 26. In other words, layers 38 are located at the PN junction. More precisely, layers 38 are located between portions of well 24′ and of layer 26. Layers 38 are preferably located so as to be in contact, for example by the lower surface, with the upper end of a wall 34. Layers 38 extend, for example, partially in front of wells 14, 16, 24′. At least a portion of wells 14, 16, 24′, corresponding to an illumination window, does not face layers 38. In other words, a portion of well 24′, more precisely the upper surface of well 24′, is for example covered by, preferably in contact with, layers 38 and another portion of well 24′, more precisely the upper surface of well 24′, preferably the rest of the upper surface of well 24′, is not covered by layers 38. Said exposed portion of well 24′ is located, for example, in front of wells 14 and 16. Said exposed portion of well 24′ is for example located in front of element 20 and/or of element 36.

The operation of pixel 32 is, for example, identical to the operation of pixel 10. The operation of pixel 32 comprises, for example, an alternation of first and second steps (or operating phases) such as described in relation with FIGS. 1A and 1B.

FIG. 3 shows a cross-section view of another embodiment of an electronic device.

The device is, for example, like the device 10 of FIGS. 1A and 1B, an optoelectronic device. The device comprises at least one pixel 40, preferably a plurality of pixels 40, for example at least one hundred pixels, for example at least one thousand pixels. For example, pixels 40 are arranged in an array. The device of FIG. 3 is, for example, configured to generate one or a plurality of electric signals on reception of light signals. For example, the device is a camera or a light sensor, for example a time-of-flight sensor.

Pixel 40 comprises elements of pixel 32 which will not be described again in detail. In particular, pixel 40 comprises: substrate 12, having surfaces 12a and 12b; wells 14, 16, and 24′ in substrate 12; element 20 located in substrate 12; layers 26, 28, 30; elements 20 and 36; and layers 38.

Pixel 40 differs from pixel 32 in that pixel 40 comprises a wall 42. Wall 42 is preferably made of an insulating material. As a variant, wall 42 may be made of a doped semiconductor material of the conductivity type opposite to that of well 14, for example P-doped.

Wall 42 divides well 14 into two portions 14a and 14b. Portions 14a and 14b are not in contact with each other. Wall 42 extends at least all along the height of well 14, preferably from surface 12a to the upper surface of well 14. Preferably, wall 42 does not extend in well 16. Preferably, wall 42 does not extend all along the height of well 16. Preferably, wall 42 does not extend in well 24′. Preferably, wall 42 does not extend all along the height of well 24′.

Portion 14b, corresponding to a reset area, is preferably biased to ground by the biasing circuit. For example, portion 14b of well 14 extends all the way to surface 12a and comprises a contact pad on surface 12a. Said pad enables, for example, to bias portion 14b to ground.

Elements 20 and 36 extend in portion 14a. Elements 20 and 36 preferably extend in a central portion of portion 14a of well 14 (but not necessarily centered therein). Thus, elements 20 and 36 are separated from walls 34 and 42, preferably from all the portions of walls 34 and 42, by portions of substrate 12, preferably by portions of well 14. Elements 20 and 36 are preferably separated from each other by portions of substrate 12.

Pixel 40 comprises an element 44. Element 44 comprises, like element 20, a conductive core and an insulating sheath. Element 44 preferably extends at least along the height of wells 14 and 16. Element 44 extends, for example, from surface 12a to the upper surface of well 16. At the end of element 44 flush with surface 12a, the conductive core of element 44 is for example exposed (meaning that it is not covered by the insulating sheath of element 44) to be electrically coupled to a voltage source of the biasing circuit, for example via conductive tracks and conductive vias of the interconnection network, not shown.

Like element 20, the conductive core of element 44 preferably comprises a lower portion and an upper portion. Said lower and upper portions are in contact with each other. Thus, the upper portion comprises a lower end in contact with the upper end of the lower portion. The upper portion preferably has horizontal dimensions greater than the horizontal dimensions of the lower portion. By horizontal, there is meant in a plane parallel to the cross-section plane B-B of FIGS. 1B and 2B.

The upper portion of element 44 is located in line with well 16. In other words, the upper portion of element 44 preferably has a height smaller than or equal to the height of well 16. More precisely, the portion of element 44 comprising the upper portion of element 44 is laterally surrounded by well 16. Preferably, the portion of element 20 comprising the upper portion of element 44 is not laterally surrounded by well 14. The upper end of the upper portion of element 44 is preferably covered by the sheath of element 44.

The lower portion of element 44 is located in line with well 14. The lower portion of element 44 preferably extends from surface 12a to the lower end of the upper portion, for example located at the interface between well 14 and well 16. More precisely, the portion of element 44 comprising the lower portion of element 44 is laterally surrounded by well 14, by the portion of substrate 12 comprising the electronic components, not shown, and optionally by a portion of well 16.

Element 44 preferably extends in a central portion of portion 14b of well 14 (but is not necessarily centered therein). Thus, element 44 is separated from walls 34 and 42, preferably from all the portions of walls 34 and 42, by portions of substrate 12, preferably by portions of well 14.

FIG. 4A and FIG. 4B illustrate the operation of the embodiment of FIG. 3. More specifically, FIGS. 4A and 4B respectively show first and second operating steps of pixel 40. Preferably, the operation of pixel 40 comprises an alternation of first and second steps (or operating phases). The operation described in relation with FIGS. 4A and 4B is, for example, of “global shutter” type.

During the first step, illustrated in FIG. 4A, charges, more precisely electrons (represented by the symbol “−”) and holes (represented by the symbol “+”), are optically generated in layer 26 on reception of light rays by layer 26. In the case of an N-doped well 24′, the electrons photogenerated in layer 26 are extracted and directed into well 24′.

During the first step or operating phase, a voltage, for example negative, is applied to layer 30 by a voltage source of the biasing circuit so that the holes are attracted out of well 24′ and towards layer 28. Further, a voltage, for example negative, is applied to the conductive core of element 36 to deplete portion 14a. A voltage, for example negative, is applied to the conductive core of element 20 by a voltage source of the biasing circuit to turn on the transistor, formed by wells 16, 24′, portion 14a, and element 20. Thus, the charges, for example the electrons, located in well 24′ are attracted into well 14a. During the first step, element 44 is configured to turn off the transistor formed by wells 16, 24′, portion 14b, and element 44.

During the second step or operating phase, a voltage, for example negative, is applied to layer 30 by a voltage source of the biasing circuit so that the holes are attracted out of well 24′ and towards layer 28. A voltage, for example negative, is applied to the conductive core of element 44 by a voltage source of the biasing circuit to turn on the transistor, formed by wells 16, 24′, portion 14b, and element 44. Thus, the charges, for example the electrons, located in well 24′ are attracted into well 14b. Further, portion 14b is for example biased to ground by said biasing circuit, to remove the charges located in portion 14b. During the second step, element 20 is configured to turn off the transistor formed by wells 16, 24′, portion 14a, and element 20. For example, the second step may comprise the reading of the charges contained in portion 14b of the well. In other words, the second step may comprise the passing of the charges located in portion 14a into a readout circuit coupled to portion 14a, the circuit being, for example, located in substrate 12 between portion 14a and surface 12a.

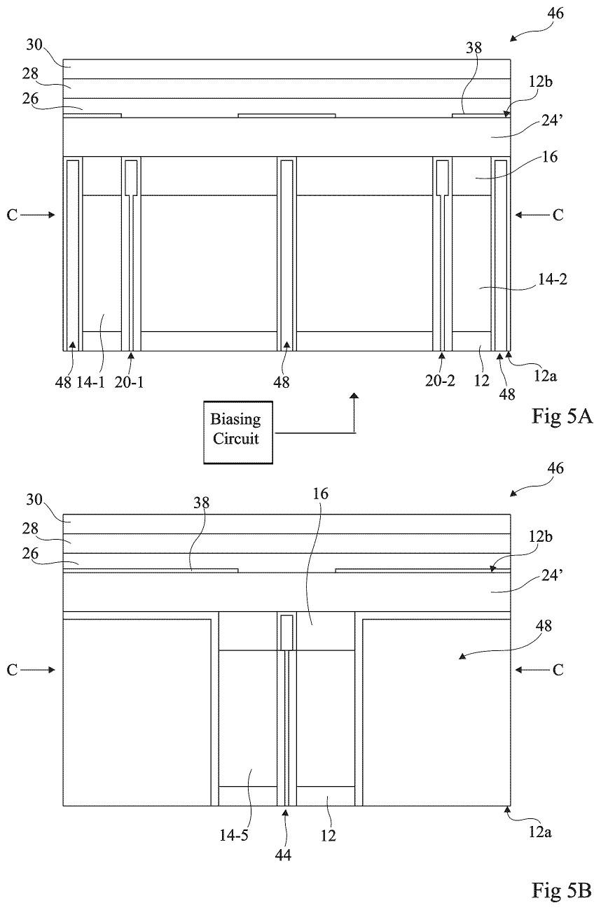

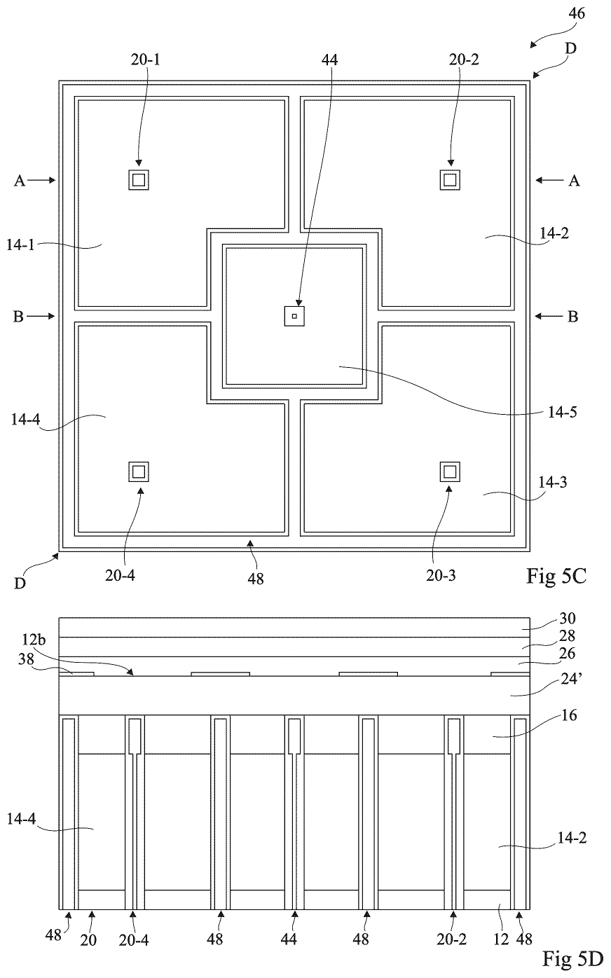

FIG. 5A shows a cross-section view of another embodiment of an electronic device. FIG. 5B shows another cross-section view of the embodiment of FIG. 5A. FIG. 5C shows a top view of the embodiment of FIG. 5A. FIG. 5D shows another cross-section view of the embodiment of FIG. 5A. More specifically, FIG. 5A is a cross-section view along plane A-A of FIG. 5C. FIG. 5B is a cross-section view along plane B-B of FIG. 5C. FIG. 5C is a top view along plane C-C of FIGS. 5A and 5B. FIG. 5B is a cross-section view along plane D-D of FIG. 5C.

The device is, for example, like the device of FIG. 3, an optoelectronic device. The device comprises at least one pixel 46, preferably a plurality of pixels 46, for example at least one hundred pixels, for example at least one thousand pixels. For example, pixels 46 are arranged in an array. The device of FIGS. 5A to 5D is, for example, configured to generate one or a plurality of electric signals on reception of light signals. For example, the device is a camera or a light sensor, for example a time-of-flight sensor.

Pixel 46 comprises elements of pixel 40 which will not be described again in detail. In particular, pixel 46 comprises: substrate 12, having surfaces 12a and 12b; wells 14, 16, and 24′ in substrate 12; element 20 located in substrate 12; layers 26, 28, 30; layers 38.

Pixel 46 differs from pixel 40 in that well 14 is divided into a plurality of portions, for example into five 14-1, 14-2, 14-3, 14-4, 14-5. One of the portions of well 14, portion 14-5 in FIGS. 5A to 5D, corresponds to a reset area, the other portions, portions 14-1 to 14-4 in FIGS. 5A to 5D, of well 14 corresponding to storage areas. Portions 14-1 to 14-4 are, for example, arranged in arrays, that is, form rows and columns, for example two rows and two columns. Portion 14-5 is for example located at the center of the array formed by portions 14-1 to 14-4.

Pixel 46 preferably does not comprise the wall 34 of FIGS. 2A to 4B. Pixel 46 comprises a wall 48. Wall 48 extends at least all along the height of well 14. Wall 48 extends, for example, from surface 12a to the upper surface of well 14, preferably from surface 12a to the upper surface of well 16. Wall 48 is, like the wall 18 of FIGS. 1A to 1C, conductive and insulated. In other words, wall 48 comprises a conductive core, for example made of metal, and an insulating outer sheath at least laterally surrounding the conductive core. Wall 48 laterally surrounds pixel 46 and further laterally surrounds the portions 14-1, 14-2, 14-3, 14-4, 14-5 of well 14. Similarly, the portions of well 16 located on the portions 14-1, 14-2, 14-3, 14-4, 14-5 of well 14 are laterally surrounded by wall 48. The side walls of the portions 14-1, 14-2, 14-3, 14-4, 14-5 of well 14 and the associated portions of well 16 are, for example, in contact with the side walls of the sheath of wall 18.

Wall 48 thus separates from one another portions 14-1 to 14-5. Thus, each of portions 14-1 to 14-4 is laterally surrounded by wall 48. The conductive core of wall 48 is configured to receive a voltage generated by a voltage source of the biasing circuit. The core of wall 48 is, for example, coupled to a node of application of said voltage by conductive tracks and conductive vias of the interconnection network, not shown. Said voltage is preferably configured to allow the depletion of well 14.

Pixel 46 comprises an element 44 extending in portion 14-5 of well 14. As described in relation with FIG. 3, element 44 preferably extends at least along the height of wells 14 and 16. Element 44 extends, for example, from surface 12a to the upper surface of well 16.

Pixel 46 comprises as many elements 20 as there are storage portions of well 14. Thus, in FIGS. 5A to 5C, pixel 46 comprises four elements 20-1, 20-2, 20-3, 20-4. Elements 20-1 to 20-4 are, for example, identical to the element 20 described in relation with FIGS. 1A and 1B. Elements 20-1, 20-2, 20-3, 20-4 respectively extend in portions 14-1, 14-2, 14-3, 14-4.

In a so-called “global shutter” operating mode, the operation of pixel 46 comprises the first and second steps described in relation with FIGS. 4A and 4B, preferably an alternation of first and second steps.

During the first steps or operating phases, a voltage, for example negative, is applied to layer 30 by a voltage source of the biasing circuit so that the holes are attracted out of well 24′ and towards layer 28. Further, a voltage, for example negative, is applied to the conductive core of wall 48 by a voltage source of the biasing circuit to deplete portions 14-1 to 14-4. A voltage, for example negative, is applied to the conductive core of elements 20-1 to 20-4 by a voltage source of the biasing circuit in such a way as to turn on the transistors, formed by wells 16, 24′, portions 14-1 to 14-4, and elements 20-1 to 20-4. Thus, the charges, for example the electrons, located in well 24′ are attracted into well 14 in one of portions 14-1 to 14-4. During the first step, element 44 is configured to turn off the transistor formed by wells 16, 24′, portion 14-5, and element 44.

During the second step or operating phase, a voltage, for example negative, is applied to layer 30 by a voltage source of the biasing circuit so that the holes are attracted out of well 24′ and towards layer 28. A voltage, for example negative, is applied to the conductive core of element 44 by a voltage source of the biasing circuit so as to turn on the transistor, comprising wells 16, 24′, portion 14-5, and element 44. Thus, the charges, for example the electrons, located in well 24′ are attracted into well 14b. Further, portion 14-5 is, for example, biased to ground by said biasing circuit, to remove the charges located in portion 14-5. During the second step, elements 20-1 to 20-4 are configured to turn off the transistors formed by wells 16, 24′, portions 14-1 to 14-4, and elements 20-1 to 20-4.

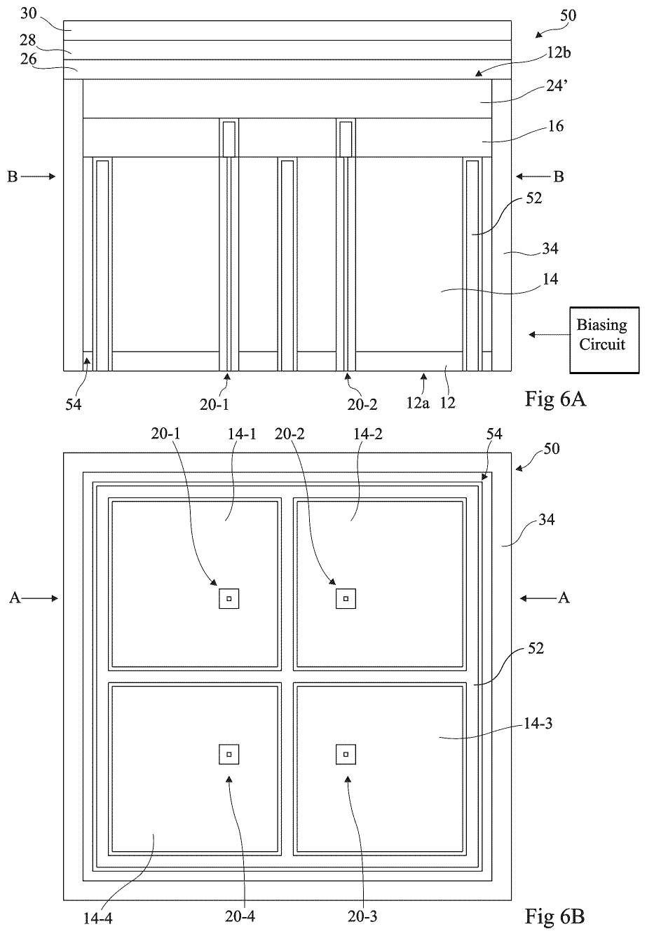

FIG. 6A shows a cross-section view of another embodiment of an electronic device. FIG. 6B shows a top view of the embodiment of FIG. 6A. More precisely, FIG. 6A is a cross-section view along plane A-A of FIG. 6B. FIG. 6B is a cross-section view along plane B-B of FIG. 6A.

The device is for example, like the device of FIGS. 5A to 5D, an optoelectronic device. The device comprises at least one pixel 50, preferably a plurality of pixels 50, for example at least one hundred pixels, for example at least one thousand pixels. For example, pixels 50 are arranged in an array. The device of FIGS. 6A and 6B is for example configured to generate one or a plurality of electric signals on reception of light signals. For example, the device is a camera or a light sensor, such as a time-of-flight sensor.

Pixel 50 comprises elements of pixel 46 or of pixel 32 which will not be described again in detail. In particular, pixel 50 comprises: the wall 34, described in relation to FIGS. 2A and 2B, surrounding pixel 50; substrate 12, having surfaces 12a and 12b; wells 16 and 24′ in substrate 12; the portions 14-1, 14-2, 14-3, 14-4 of well 14; elements 20-1, 20-2, 20-3, 20-4 located in substrate 12; and layers 26, 28, 30.

Pixel 50 differs from pixel 46 in that pixel 50 does not comprise portion 14-5 and does not comprise element 44. Further, pixel 50 does not comprise layers 38.

In pixel 50, each portion 14-1 to 14-4, corresponding to a storage region, is surrounded by a wall 52. The walls 52 surrounding the different portions 14-1 to 14-4 have, for example, common parts and form, for example, a single wall 52 surrounding each of portions 14-1 to 14-4.

Wall 52 is, for example, similar to the wall 18 of FIGS. 1A and 1B and to the wall 48 of FIGS. 5A to 5D. Wall 52 is conductive and insulated. In other words, wall 52 comprises a conductive core, for example made of metal, and an insulating outer sheath at least laterally surrounding the conductive core. Wall 52 laterally surrounds portions 14-1 to 14-4. The side walls of portions 14-1 to 14-4 are, for example, in contact with the side walls of the sheath of wall 52.

Wall 52 extends at least along the height of portions 14-1 to 14-4. In other words, wall 52 extends at least along the side walls of portions 14-1 to 14-4. Preferably, wall 52 extends from surface 12a to the upper surface of portions 14-1 to 14-4.

The conductive core of wall 52 is configured to receive a voltage generated by a voltage source of the biasing circuit. The core of wall 52 is, for example, coupled to a node of application of said voltage by conductive tracks and conductive vias of the interconnection network, not shown. Said voltage is preferably configured to allow the depletion of portions 14-1 to 14-4.

Wall 52 is, for example, separated from wall 34 by a portion 54 of substrate 12, for example comprising a portion of well 14.

During a so-called “rolling shutter” operating mode, the operation of the pixel comprises as many steps (or operating phases) as there are storage regions 14-1 to 14-4. Thus, in the example of FIGS. 6A and 6B, the operation of pixel 50 comprises first, second, third, and fourth steps. More specifically, the operation of pixel 50 comprises the repetition of the first, second, third, and fourth steps, preferably in this order.

Each first, second, third, and fourth step corresponds to the storage of charges in one of the storage regions. Thus, during each step, the charges, for example the electrons, are attracted to one of the storage regions, said region being different in each of the first, second, third, and fourth steps. More precisely, the transistor allowing the passing into said storage region is turned on, and the other transistors allowing the passing into the other storage regions are kept off. The other charges, for example the holes, are attracted into layer 28.

In the first, second, third, and fourth steps, a voltage, for example negative, is applied to layer 30 by a voltage source of the biasing circuit so that holes optically generated in layer 26 are attracted out of layer 26 and towards layer 28. Further, a voltage, for example negative, is applied to the conductive core of wall 52 by a voltage source of the biasing circuit in such a way as to deplete portions 14-1 to 14-4.

Further, during the first step, a voltage, for example positive, is applied to the conductive core of element 20-1 by a voltage source of the biasing circuit in such a way as to turn on the transistor, for example a vertical MOSFET transistor, formed by the portion of well 16 surrounding the element 20-1 forming the gate, the portion of well 24′ adjacent to said portion of well 16, and portion 14-1. Thus, the charges, for example the electrons, previously photogenerated in layer 26 and extracted in well 24′ are attracted into portion 14-1. During the first step, elements 20-2 to 20-4 are configured to turn off the transistors formed by wells 16, 24′, portions 14-2 to 10-4, and elements 20-2 to 20-4. During the first step, the charges contained in portions 14-2 to 14-4 are, for example, read out by a readout circuit, not shown, for example comprising electronic components located inside and on top of substrate 12.

Similarly, during the second step, a voltage, for example positive, is applied to the conductive core of element 20-2 by a voltage source of the biasing circuit in such a way as to turn on the transistor, formed by wells 16, 24′, portion 14-2, and element 20-2. Thus, the charges, for example the electrons, located in well 24′ are attracted into portion 14-2. During the second step, elements 20-1, 20-3, and 20-4 are configured to turn off the transistors formed by wells 16, 24′, portions 14-1, 14-3, and 10-4, and elements 20-1, 20-3, and 20-4. During the second step, the charges contained in portions 14-1, 14-3, and 14-4 are, for example, read out by a readout circuit, not shown, for example comprising electronic components located inside and on top of substrate 12.

Similarly, during the third step, a voltage, for example positive, is applied to the conductive core of element 20-3 by a voltage source of the biasing circuit in such a way as to turn on the transistor, formed by wells 16, 24′, portion 14-3, and element 20-3. Thus, the charges, for example the electrons, located in well 24′ are attracted into portion 14-3. During the third step, elements 20-1, 20-2, and 20-4 are configured to turn off the transistors formed by wells 16, 24′, portions 14-1, 14-2, and 10-4, and elements 20-1, 20-2, and 20-4. During the third step, the charges contained in portions 14-1, 14-2, and 14-4 are, for example, read out by a readout circuit, not shown, for example comprising electronic components located inside and on top of substrate 12.

Similarly, during the fourth step, a voltage, for example positive, is applied to the conductive core of element 20-4 by a voltage source of the biasing circuit so as to turn on the transistor, formed by wells 16, 24′, portion 14-4, and element 20-4. Thus, the charges, for example the electrons, located in well 24′ are attracted into portion 14-4. During the fourth step, elements 20-1, 20-2, and 20-3 are configured to turn off the transistors formed by wells 16, 24′, portions 14-1, 14-2, and 10-3, and elements 20-1, 20-2, and 20-3. During the fourth step, the charges contained in portions 14-1, 14-2, and 14-3 are, for example, read out by a readout circuit, not shown, for example comprising electronic components located inside and on top of substrate 12.

Various embodiments and variants have been described. Those skilled in the art will understand that certain features of these various embodiments and variants may be combined, and other variants will occur to those skilled in the art. In particular, the doping types could be reversed. Layer 30 would then be configured to receive a voltage attracting electrons into layer 28, and elements 20 or 20-1 to 20-4 and 44 would then be configured to receive a voltage allowing the passing of holes into well 14.

Finally, the practical implementation of the described embodiments and variants is within the abilities of those skilled in the art based on the functional indications given hereabove.

1. An optoelectronic device, comprising:
at least one pixel, wherein the at least one pixel comprises:
a first semiconductor region of a first conductivity type;
a second semiconductor region of a second conductivity type, different from the first conductivity type, resting on the first semiconductor region;
an insulating wall surrounding the first and second semiconductor regions;
a photodiode resting on the second semiconductor region, the photodiode comprising a third semiconductor region of the first conductivity type, the third semiconductor region being in contact with the second semiconductor region and being separated from the first semiconductor region by the second semiconductor region; and
a first conductive and insulated element under the third semiconductor region and extending through at least the second semiconductor region; and
a biasing circuit configured to bias the first conductive and insulated element with a first voltage during a first operating step to allow the passing of charges from the third semiconductor region to the first semiconductor region.

2. The device according to claim 1, wherein the first conductive and insulated element is a via extending through the first and second semiconductor regions and comprising a conductive core and an insulating sheath.

3. The device according to claim 2, wherein the conductive core of the first conductive and insulated element comprises a first portion surrounded by the first semiconductor region and a second portion surrounded by the second semiconductor region, the second portion having horizontal dimensions greater than the horizontal dimensions of the first portion.

4. The device according to claim 1, wherein the photodiode comprises the third semiconductor region of the first conductivity type and a fourth doped region of the second conductivity type, the third semiconductor region comprising first and second layers forming a heterojunction, the first layer being made of a semiconductor material and the second layer comprising quantum dots, the fourth doped region being in contact with the second layer, wherein a dopant concentration of the first layer is greater than a dopant concentration of the second layer.

5. The device according to claim 1, wherein the insulating wall comprises a first insulated conductive wall, and wherein the biasing circuit is configured to bias the first insulated conductive wall to deplete the first semiconductor region.

6. The device according to claim 1, wherein the pixel further comprises a second conductive and insulated element extending in the first semiconductor region parallel to but separated from the first conductive and insulated element.

7. The device according to claim 1, wherein the first semiconductor region is divided into a first portion and a second portion, the first conductive and insulated element being located in the second semiconductor region, in front of the first portion of the first semiconductor region, the first and second portions of the first semiconductor region being separated by a third insulating wall, the pixel comprising a third element, the third element being conductive and insulated, extending in the second semiconductor region in front of the second portion of the first semiconductor region, and wherein the biasing circuit is configured to bias the third element by a second voltage during a second operating step to allow the passing of charges from the third semiconductor region to the second portion of the first semiconductor region.

8. The device according to claim 7, wherein the biasing circuit is configured to bias the third element during the first operating step by a third voltage to block the passing of charges from the third semiconductor region to the second portion of the first semiconductor region, and wherein the biasing circuit is configured to bias the first conductive and insulated element by a fourth voltage during the second operating step to block the passing of charges from the third semiconductor region to the first portion of the first semiconductor region.

9. The device according to claim 1, wherein the first semiconductor region is divided into at least two first portions and a second portion, the pixel comprising as many first conductive and insulated elements as there are first portions, each first conductive and insulated element being located in the second semiconductor region in front of one of the first portions of the first semiconductor region, the first and second portions of the first semiconductor region being separated from one another by a third insulating wall, the pixel comprising a third element, the third element being conductive and insulated, extending in the second semiconductor region in front of the second portion of the first semiconductor region, and wherein the biasing circuit is configured to bias the third element by a second voltage during a second operating step to allow the passing of charges from the third semiconductor region to the second portion of the first semiconductor region.

10. The device or method according to claim 9, wherein the pixel comprises as many insulated conductive second elements as there are first portions of the first semiconductor region, each insulated conductive second element extending in one of the first portions of the first semiconductor region.

11. The device according to claim 10, wherein the biasing circuit is configured during the first operating step to bias the third element by a third voltage to block the passing of charges from the third semiconductor region to the second portion of the first semiconductor region and wherein the biasing circuit is configured during the second operating step to bias the first conductive and insulated elements by a fourth voltage to block the passing of charges from the third semiconductor region to the first portions of the first semiconductor region.

12. The device according to claim 1, wherein the first semiconductor region is divided into at least two first portions, the pixel comprising as many first conductive and insulated elements as there are first portions, each first conductive and insulated element being located in the second semiconductor region in front of one of the first portions of the first semiconductor region.

13. The device according to claim 12, wherein the pixel is configured to operate in a succession of steps, each step comprising the application of a voltage by the biasing circuit to the first conductive and insulated element of one of the first portions to allow the passing of charges to said first portion and the application of a voltage by the biasing circuit to the other first conductive and insulated elements to block the passing of charges to the other first portions.

14. The device according to claim 13, wherein each first portion is surrounded by a first insulated conductive wall, and wherein the biasing circuit is configured to bias the first insulated conductive wall to deplete said first semiconductor region.
